(19) United States
(12) Patent Application Publication
(10) Pub. No.: US 2026/0190499 A1
(43) Pub. Date: Jul. 2, 2026

(54) ELECTROSTATIC DISCHARGE PROTECTION STRUCTURE AND DEVICE

(71) Applicant: Vanguard International Semiconductor Corporation, Hsinchu (TW)

(72) Inventors: Ting-Yu CHANG, Zhubei City (TW); Chih-Hsuan LIN, Hsinchu City (TW); Chieh-Yao CHUANG, Kaohsiung City (TW); Hsien-Feng LIAO, Taichung City (TW); Yeh-Ning JOU, Hsinchu City (TW); Jian-Hsing LEE, Hsinchu City (TW)

(73) Assignee: Vanguard International Semiconductor Corporation, Hsinchu (TW)

(21) Appl. No.: 19/008,428

(22) Filed: Jan. 2, 2025

(51) Int. Cl. H10D 89/60

(52) U.S. Cl. CPC H10D 89/713

(57) ABSTRACT

An electrostatic discharge (ESD) protection structure is provided. A substrate has a first conductivity type. A first well is disposed in the substrate and has a second conductivity type. A second well and a first doped region are disposed in the first well and have the first conductivity type. A second doped region is disposed in the second well and has the second conductivity type. A third well is disposed in the substrate and has the second conductivity type. A fourth well is disposed in the third well and has the first conductivity type. A third doped region is disposed in the fourth well and has the second conductivity type. A fourth doped region is disposed in the third well and has the first conductivity type. A separation structure is disposed in the substrate to separate the first well from the third well.

### BACKGROUND OF THE INVENTION

### Field of the Invention

The present invention relates to an electrostatic discharge (ESD) protection structure, and, in particular, it relates to a bi-directional ESD protection structure.

### Description of the Related Art

As the semiconductor manufacturing process develops, electrostatic discharge (ESD) protection has become one of the most critical reliability issues for integrated circuits (IC). In particular, as semiconductor processing advances into the deep sub-micron stage, scaled-down devices and thinner gate oxides are more vulnerable to ESD stress.

### BRIEF SUMMARY OF THE INVENTION

In accordance with an embodiment of the disclosure, an electrostatic discharge (ESD) protection structure comprises a substrate, a first well, a second well, a first doped region, a second doped region, a third well, a fourth well, a third doped region, a fourth doped region, and a separation structure. The substrate has a first conductivity type. The first well is disposed in the substrate and has a second conductivity type. The second well is disposed in the first well and has the first conductivity type. The first doped region is disposed in the first well and has the first conductivity type. The second doped region is disposed in the second well and has the second conductivity type. The third well is disposed in the substrate and has the second conductivity type. The fourth well is disposed in the third well and has the first conductivity type. The third doped region is disposed in the fourth well and has the second conductivity type. The fourth doped region is disposed in the third well and has the first conductivity type. The separation structure is disposed in the substrate to separate the first well from the third well.

In accordance with another embodiment of the disclosure, an ESD protection device protects a core circuit coupled between a first power terminal and a second power terminal, and comprises a substrate, a first well, a second well, a first doped region, a second doped region, a third well, a fourth well, a third doped region, a fourth doped region, and a separation structure. The substrate has a first conductivity type. The first well is disposed in the substrate and has a second conductivity type. The second well is disposed in the first well and has the first conductivity type. The first doped region is disposed in the first well and has the first conductivity type. The second doped region is disposed in the second well and has the second conductivity type. The third well is disposed in the substrate and has the second conductivity type. The fourth well is disposed in the third well and has the first conductivity type. The third doped region is disposed in the fourth well and has the second conductivity type. The fourth doped region is disposed in the third well and has the first conductivity type. The separation structure is disposed in the substrate to separate the first well from the second well. The first and second doped regions are coupled to the first power terminal. The third and fourth doped regions are coupled to the second power terminal.

### BRIEF DESCRIPTION OF THE DRAWINGS

The present invention can be more fully understood by reading the subsequent detailed description and examples with references made to the accompanying drawings, wherein:

FIG. 1 is a schematic diagram of an exemplary embodiment of a controller system according to various aspects of the present disclosure.

FIG. 2 is a schematic diagram of an exemplary embodiment of an electrostatic discharge (ESD) protection device according to various aspects of the present disclosure.

FIG. 3 is a schematic diagram of another exemplary embodiment of the ESD protection structure according to various aspects of the present disclosure.

FIG. 4 is a schematic diagram of another exemplary embodiment of the ESD protection structure according to various aspects of the present disclosure.

### DETAILED DESCRIPTION OF THE INVENTION

The present invention will be described with respect to particular embodiments and with reference to certain drawings, but the invention is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the invention.

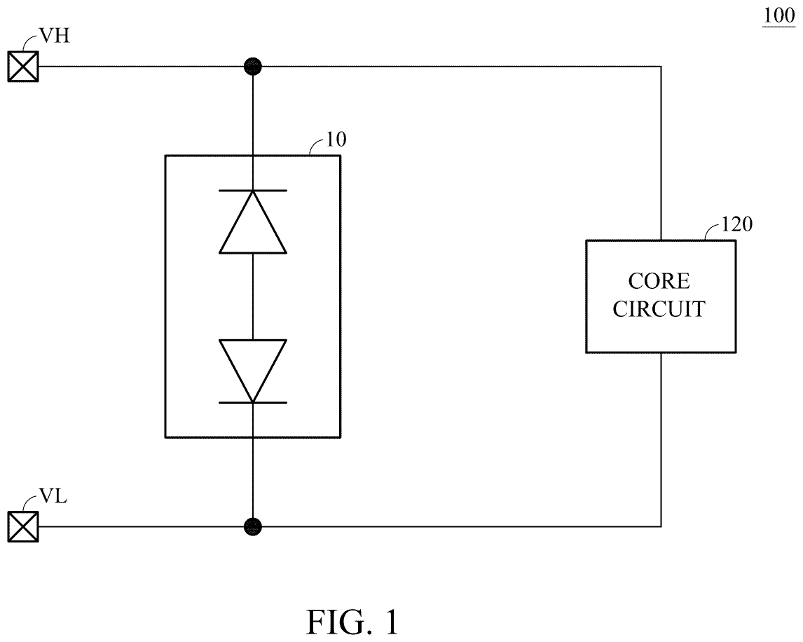

FIG. 1 is a schematic diagram of an exemplary embodiment of a controller system according to various aspects of the present disclosure. The control system 100 comprises an electrostatic discharge (ESD) protection device 110 and a core circuit 120. The ESD protection device 110 and the core circuit 120 are coupled between power terminals VH and VL. In this embodiment, the ESD protection device 110 is a bi-directional protection element to release an ESD current from the power terminal VH or VL to prevent the ESD current from damaging the core circuit 120.

For example, when a first ESD event occurs on the power terminal VH and the power terminal VL receives a ground voltage, the ESD protection device 110 is turned on to release a first ESD current from the power terminal VH to the power terminal VL. When a second ESD event occurs on the power terminal VL and the power terminal VH receives a ground voltage, the ESD protection device 110 is turned on to release a second ESD current from the power terminal VL to the power terminal VH.

The type of the ESD protection device 110 is not limited in the present disclosure. In one embodiment, the ESD protection device 110 comprises a symmetric dual silicon controlled rectifier. In some embodiments, in a normal mode (no ESD event), the power terminal VH receives a first operation voltage, and the power terminal VL receives a second operation voltage. At this time, the ESD protection device 110 is turned off, and the core circuit 120 normally works according to the first and second operation voltages. In one embodiment, the first operation voltage is higher than the second operation voltage.

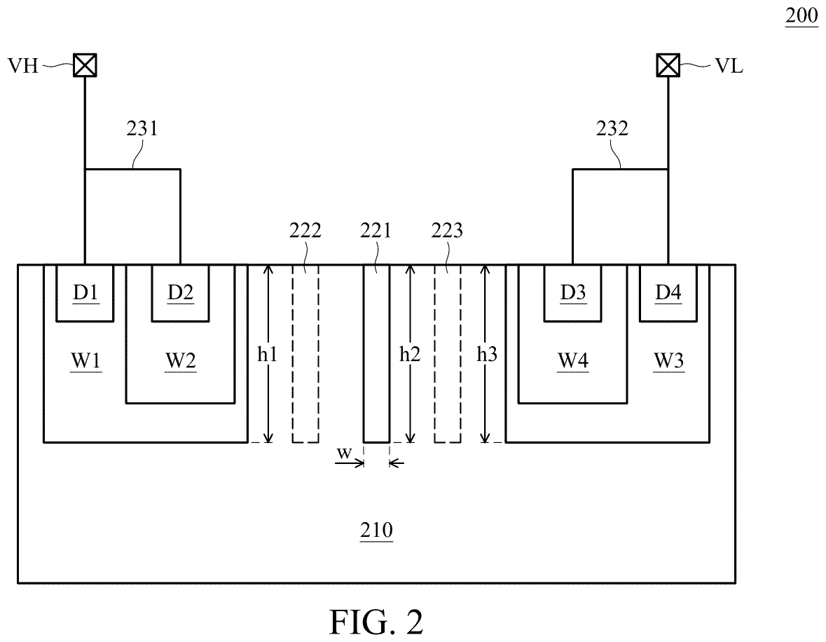

FIG. 2 is a schematic diagram of an exemplary embodiment of the ESD protection device 110 according to various aspects of the present disclosure. As shown in FIG. 2, an ESD protection structure 200 comprises a substrate 210, wells W1˜W4, doped regions D1˜D4, and a separation structure 221. The substrate 210 has a first conductivity type. The wells W1 and W3 are disposed in the substrate 210. The depth h1 of the well W1 is similar to the depth h3 of the well W3. In this embodiment, each of the wells W1 and W3 has a second conductivity type. The doping concentration of the well W1 is the same as the doping concentration of the well W3. In one embodiment, the first conductivity type is P-type, and the second conductivity type is N-type. In another embodiment, the first conductivity type is N-type, and the second conductivity type is P-type.

The doped region D1 and the well W2 are disposed in the well W1 and has the first conductivity type. In one embodiment, the doping concentration of the doped region D1 is higher than the doping concentration of the well W2. In this case, the doping concentration of the well W2 is higher than the doping concentration of the substrate 210. The doped region D2 is disposed in the well W2 and has the second conductivity type. In one embodiment, the doping concentration of the doped region D2 is higher than the doping concentration of the well W1.

The well W4 and the doped region D4 are disposed in the well W3 and has the first conductivity type. In one embodiment, the doping concentration of the doped region D4 is higher than the doping concentration of the well W4. In this case, the doping concentration of the well W4 is higher than the doping concentration of the substrate 210. In some embodiments, the doping concentration of the doped region D4 is the same as the doping concentration of the doped region D1, and the doping concentration of the well W4 is the same as the doping concentration of the well W2. The doped region D3 is disposed in the well W4 and has the second conductivity type. In one embodiment, the doping concentration of the doped region D3 is higher than the doping concentration of the well W3. In some embodiment, the doping concentration of the doped region D3 is the same as the doping concentration of the doped region D2.

The separation structure 221 is disposed in the substrate 210 to separate the well W1 from the well W3. The kind of separation structure 221 is not limited in the present disclosure. In one embodiment, the separation structure 221 is a deep trench isolation DTI structure. In this embodiment, the separation structure 221 does not receive any voltage. Therefore, the voltage level of the separation structure 221 is a floating level.

In one embodiment, the depth h2 of the separation structure 221 is the same as the depth of the well W1 and the depth h3 of the well W3, but the disclosure is not limited in the present disclosure. In another embodiment, the depth h2 of the separation structure 221 is larger than the depth h1 of the well W1 and the depth h3 of the well W3. Therefore, the bottom of the separation structure 221 is closer to the bottom of the substrate 210 than the bottoms of the wells W1 and W3.

In some embodiments, the width w of the separation structure 221 is adjusted to control the depth h2 of the separation structure 221. For example, with increase of the width w of the separation structure 221, the depth h2 of the separation structure 221 is also increased. With decrease of the width w of the separation structure 221, the depth h2 of the separation structure 221 is also reduced.

The number of separation structure is not limited in the present disclosure. The ESD protection structure 200 may comprise the more separation structures. Each separation structure is disposed between the wells W1 and W3. For example, the ESD protection structure 200 further comprises a separation structure 222. The separation structure 222 is disposed in the substrate 210 to separate the well W1 from the separation structure 221. The depth of the separation structure 222 is similar to the depth h2 of the separation structure 221, but the disclosure is not limited in the present disclosure. In other embodiments, the depth of the separation structure 222 may be larger than or less than the depth h2 of the separation structure 221.

In another embodiment, the ESD protection structure 200 further comprises a separation structure 223. The separation structure 223 is disposed in the substrate 210to separate the separation structure 221 and the well W3. In this case, the depth of the separation structure 223 is similar to the depth h2 of the separation structure 221, but the disclosure is not limited in the present disclosure. In other embodiments, the depth of the separation structure 223 may be larger than or less than the depth h2 of the separation structure 221.

In some embodiments, the ESD protection structure 200 further comprises interconnection structures 231 and 232. The interconnection structure 231 are electrically connected to the doped regions D1 and D2, and the power terminal VH. The interconnection structure 232 is electrically connected to the doped regions D3 and D4, and the power terminal VL. When a first ESD event occurs on the power terminal VH and the power terminal VL receives a ground voltage, a first ESD current passes from the power terminal VH, through the doped region D1, the well W1, the substrate 210, the wells W3 and W4, and the doped region D3, and to the power terminal VL. When a second ESD event occurs on the power terminal VL and the power terminal VH receives a ground voltage, a second ESD current passes from the power terminal VL, through the doped region D4, the well W3, the substrate 210, the wells W1 and W2, and the doped region D2, and to the power terminal VH.

When there is no ESD event, the power terminal VH receives a first operation voltage, and the power terminal VL receives a second operation voltage. Assume that the first operation voltage is higher than the second operation voltage. Since the PN junction between the doped region D1 and the well W1 is forward turned on, the voltage of the well W1 is increased causing the diffusion of the well W1 in the substrate 210. When the well W1 contacts the well W3, the leakage current passing through the ESD protection structure 200 is increased. However, since the separation structure 221 is disposed between the wells W1 and W3, the well W1 does not contact the well W3. Therefore, the leakage passing through the ESD protection structure 200 is reduced and the breakdown voltage of the ESD protection structure 200 is increased.

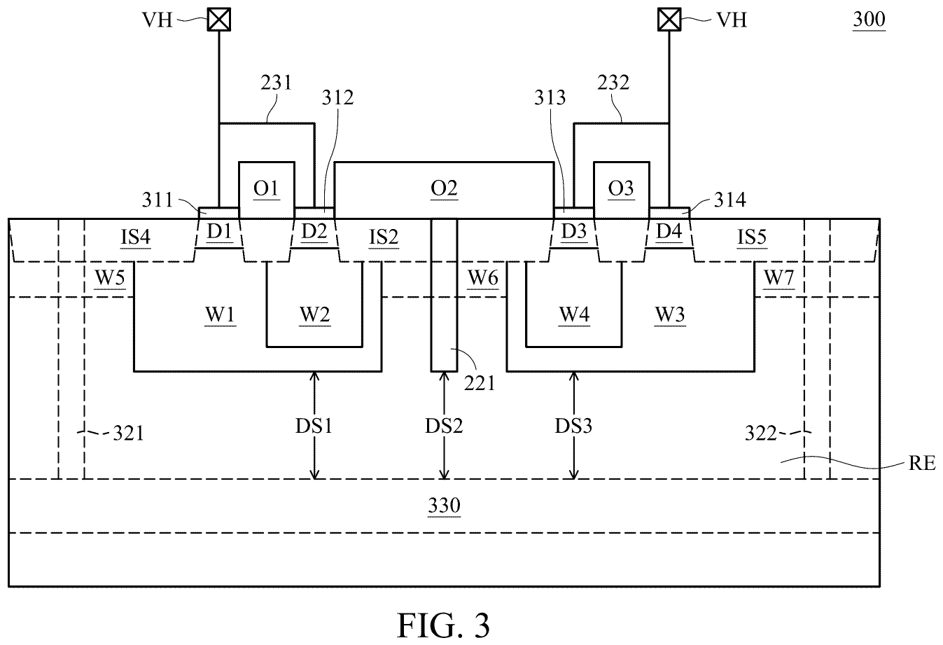

FIG. 3 is a schematic diagram of another exemplary embodiment of the ESD protection structure according to various aspects of the present disclosure. FIG. 3 is similar to FIG. 2 with the exception that the ESD protection structure 300 further comprises metal contact terminals 311˜314. The metal contact terminal 311 overlaps the doped region D1 and is electrically connected to the interconnection structure 231. The metal contact terminal 313 overlaps the doped region D2 and is electrically connected to the interconnection structure 231. The metal contact terminal 313 overlaps the doped region D3 and is electrically connected to the interconnection structure 232. The metal contact terminal 314 overlaps the doped region D4 and is electrically connected to the interconnection structure 232.

In some embodiments, the ESD protection structure 300 further comprises resist protection oxides O1˜O3. The resist protection oxide O1 isolates the metal contact terminals 311 and 312. The resist protection oxide O2 isolates the metal contact terminals 312 and 313. The resist protection oxide O3 isolates the metal contact terminals 313 and 314.

In other embodiments, the ESD protection structure 300 further comprises isolation structures IS1˜IS3. The isolation structure IS1 isolates the doped regions D1 and D2. The isolation structure IS2 isolates the doped regions D2 and D3. In this embodiment, the separation structure 221 penetrates through the isolation structure IS2. The isolation structure IS3 isolates the doped regions D3 and D4. In this case, the isolation structure IS1 is disposed under the resist protection oxide O1 and contacts the resist protection oxide O1, the isolation structure IS2 is disposed under the resist protection oxide O2 and contacts the resist protection oxide O2, and the isolation structure IS3 is disposed under the resist protection oxide O3 and contacts the resist protection oxide O3.

In one embodiment, the ESD protection structure 300 comprises isolation structures IS1˜IS3. In this case, the resist protection oxides O1˜O3 are omitted. The kinds of isolation structures IS1˜IS3 are shallow trench isolation structures.

In some embodiments, the ESD protection structure 300 further comprises separation structures 321 and 322, and an oxide 330. In this case, the ESD protection structure 300 is manufactured by silicon on insulator (SOI) process. The separation structures 321, 322, and the oxide 330 are disposed in the substrate 210. The separation structure 321 is located to the left-side of the well W1 and contacts the oxide 330. The separation structure 322 is located to the right-side of the well W3 and contacts the oxide 330. In one embodiment, the oxide 330, the separation structures 321 and 322 define an element region RE. The wells W1 and W3 are disposed in the element region RE. In this embodiment, the depths of the separation structures 321 and 322 are larger than the depth of the separation structure 221. In this case, the separation structure 221 does not contact the oxide 330.

In some embodiments, there is a distance DS2 between the bottom of the separation structure 221 and the top of the oxide 330. The distance DS2 is similar to the distance DS1 between the bottom of the well W1 and the top of the oxide 330, and the distance DS3 between the bottom of the well W3 and the top of the oxide 330. In one embodiment, the distance DS2 may be larger than or shorter than the distances DS1 and DS3. For example, the bottom of the separation structure 221 is closer to the top of the oxide 330 than the bottom of the wells W1 and W3.

In some embodiments, the ESD protection structure 300 further comprises isolation structures IS4 and IS5. The isolation structure IS4 is disposed in the substrate 210 and overlaps a portion of well W1. As shown in FIG. 3, the doped region D1 is located between the isolation structures IS1 and IS4. The isolation structure IS5 is disposed in the substrate 210 and overlaps a portion of well W3. The doped region D4 is located between the isolation structures IS3 and IS5. In this case, the separation structure 321 penetrates through the isolation structure IS4. The separation structure 322 penetrates through the isolation structure IS5.

In other embodiments, the ESD protection structure 300 further comprises wells W5˜W7. The wells W5˜W7 are disposed in the substrate 210. Each of the wells W5˜W7 has the first conductivity type. In this case, the well W5 is disposed under the isolation structure IS4 and contacts the well W1. The doping concentration of the well W5 is similar to the doping concentration of the well W2. In one embodiment, the separation structure 321 penetrates through the isolation structure IS4 and the well W5. The doping concentration of the well W6 is disposed under the isolation structure IS2 and contacts the wells W1 and W3. The doping concentration of the well W6 is similar to the doping concentration of the well W5. In one embodiment, the separation structure 221 penetrates through the isolation structure IS2 and the well W6. The well W7 is disposed under the isolation structure IS5 and contacts the well W3. The doping concentration of the well W7 is similar to the doping concentration of the well W5. In one embodiment, the separation structure 322 penetrates through the isolation structure IS5 and the well W7.

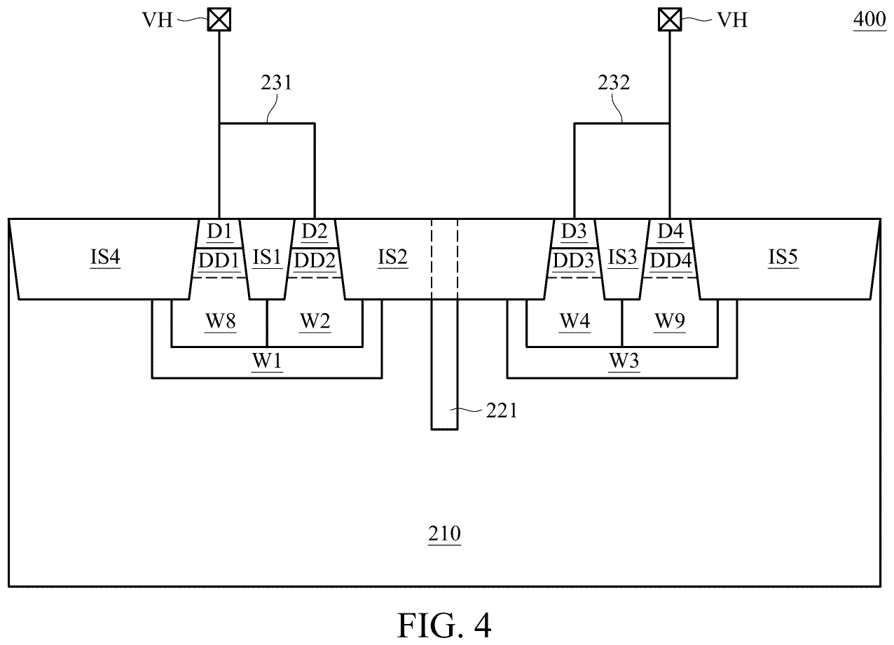

FIG. 4 is a schematic diagram of another exemplary embodiment of the ESD protection structure according to various aspects of the present disclosure. FIG. 4 is similar to FIG. 2 with the exception that the ESD protection structure 400 further comprises wells W8 and W9. The well W8 is disposed in the well W1 and has the second conductivity type. The doped region D1 is disposed in the well W8. In this case, the doping concentration of the well W8 is higher than the doping concentration of the of the well W1 and lower than the doping concentration of the doped region D2. In this case, the well W1 can withstand high voltage better than the well W8, the well W1 can be referred to as a high-voltage well.

The well W9 is disposed in the well W3 and has the second conductivity type. The doped region D4 is disposed in the well W9. In this case, the doping concentration of the well W9 is higher than the doping concentration of the of the well W3 and lower than the doping concentration of the doped region D3. In this case, the well W3 can withstand high voltage better than the well W9, the well W3 can be referred to as a high-voltage well.

In other embodiments, the ESD protection structure 400 further comprises drift regions DD1˜DD4. The drift region DD1 is disposed in the well W8 and has the first conductivity type. The drift region DD2 is disposed in the well W2 and having the second conductivity type. The drift region DD3 is disposed in the well W4 and has the second conductivity type. The drift region DD4 is disposed in the well W9 and has the first conductivity type.

The doped region D1 is disposed in the drift region DD1. In one embodiment, the doping concentration of the doped region D1 is higher than the doping concentration of the drift region DD1. The doped region D2 is disposed in the drift region DD2. In one embodiment, the doping concentration of the doped region D2 is higher than the doping concentration of the drift region DD2. The doped region D3 is disposed in the drift region DD3. In one embodiment, the doping concentration of the doped region D3 is higher than the doping concentration of the drift region DD3. The doped region D4 is disposed in the drift region DD4. In one embodiment, the doping concentration of the doped region D4 is higher than the doping concentration of the drift region DD4.

In one embodiment, the drift regions DD1˜DD4 are dropped drift regions. For example, assume that the first conductivity type is P-type and the second conductivity type is N-type. In this case, each of the drift regions DD1 and DD4 is referred to as a P-type dropped drift region (PDD). Each of the drift regions DD2 and DD3 is referred to as a N-type dropped drift region (NDD).

In other embodiments, the ESD protection structure 400 further comprises isolation structures IS1˜IS5. The isolation structure IS1 is disposed between the doped regions D1 and D2. The isolation structure IS2 is disposed between the doped regions D2 and D3. The isolation structure IS3 is disposed between the doped regions D3 and D4. In this case, the doped region D1 is disposed between the isolation structures IS4 and IS1, and the doped region D4 is disposed between the isolation structures IS3 and IS5.

When a first ESD event occurs on the power terminal VH and the power terminal VL receives a ground voltage, an ESD current passes from the power terminal VH and through the doped region D1, the drift region DD1, the wells W8 and W1, the substrate 210, and the well W3. After entering the well W3, the ESD current passes through the well W4, the drift region DD3, the doped region D3 and to the power terminal VL, or passes through the well W9, the drift region DD4, the doped region D4 and to the power terminal VL.

When a second ESD event occurs on the power terminal VL and the power terminal VH receives a ground voltage, an ESD current passes from the power terminal VL and through the doped region D4, the drift region DD4, the wells W9 and W3, the substrate 210, and the well W1. After entering the well W1, the ESD current passes through the well W8, the drift region DD1, the doped region D1 and to the power terminal VH, or passes through the well W2, the drift region DD2, the doped region D2 and to the power terminal VH.

In some embodiments, the ESD protection structure 400 further comprises the separation structure 321 and 322, and the oxide 330 shown in FIG. 3. In another embodiment, the ESD protection structure 400 further comprises the separation structure 222 and 223 shown in FIG. 2 and the well W6 shown in FIG. 3. In this case, the separation structures 221˜223 penetrate through the isolation structure IS2 and the well W6.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. It will be understood that although the terms “first,” “second,” etc. may be used herein to describe various elements, these elements should not be limited by these terms. These terms are only used to distinguish one element from another. In the following claims, the terms “first,” “second,” etc. are used merely as labels, and are not intended to impose numerical requirements on their objects.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electrostatic discharge (ESD) protection structure, comprising:
a substrate having a first conductivity type;
a first well disposed in the substrate and having a second conductivity type;
a second well disposed in the first well and having the first conductivity type;
a first doped region disposed in the first well and having the first conductivity type;
a second doped region disposed in the second well and having the second conductivity type;
a third well disposed in the substrate and having the second conductivity type;
a fourth well disposed in the third well and having the first conductivity type;
a third doped region disposed in the fourth well and having the second conductivity type;
a fourth doped region disposed in the third well and having the first conductivity type; and
a first separation structure disposed in the substrate to separate the first well from the third well.

2. The ESD protection structure as claimed in claim 1, further comprising:
a second separation structure disposed in the substrate to separate the first well from the first separation structure.

3. The ESD protection structure as claimed in claim 1, further comprising:
a first interconnection structure electrically connected to the first and second doped regions; and
a second interconnection structure electrically connected to the third and fourth doped regions.

4. The ESD protection structure as claimed in claim 3, further comprising:
a first metal-contact terminal overlapping the first doped region and electrically connected to the first interconnection structure;
a second metal-contact terminal overlapping the second doped region and electrically connected to the first interconnection structure;
a third metal-contact terminal overlapping the third doped region and electrically connected to the second interconnection structure;
a fourth metal-contact terminal overlapping the fourth doped region and electrically connected to the second interconnection structure;
a first resist protective oxide separating the first metal-contact terminal from the second metal-contact terminal;
a second resist protective oxide separating the second metal-contact terminal from the third metal-contact terminal; and
a third resist protective oxide separating the third metal-contact terminal from the fourth metal-contact terminal.

5. The ESD protection structure as claimed in claim 3, further comprising:
a fifth well disposed in the first well and having the second conductivity type; and
a sixth well disposed in the third well and having the second conductivity type,
wherein the first doped region is disposed in the fifth well, and the fourth doped region is disposed in the sixth well.

6. The ESD protection structure as claimed in claim 5, further comprising:
a first isolation structure isolating the first doped region from the second doped region;
a second isolation structure isolating the third doped region from the fourth doped region; and
a third isolation structure isolating the second doped region from the third doped region.

7. The ESD protection structure as claimed in claim 6, wherein the first isolation structure penetrates through the third isolation structure.

8. The ESD protection structure as claimed in claim 6, further comprising:
a seventh well disposed under the third isolation structure.

9. The ESD protection structure as claimed in claim 8, wherein the first isolation structure penetrates the third isolation structure and the seventh well.

10. The ESD protection structure as claimed in claim 6, further comprising:
an oxide disposed in the substrate;
a third separation structure disposed in the substrate and contacting the oxide; and
a fourth separation structure disposed in the substrate and contacting the oxide,
wherein the oxide, the third separation structure, and the fourth separation structure define an element region, and the first and third wells are disposed in the element region.

11. The ESD protection structure as claimed in claim 10, wherein there is a first distance between the first well and the oxide, there is a second distance between the first separation structure and the oxide, there is a third distance between the third well and the oxide, and the second distance is shorter than the first and the third distances.

12. The ESD protection structure as claimed in claim 5, further comprising:
a first drift region disposed in the fifth well and having the first conductivity type;
a second drift region disposed in the second well and having the second conductivity type;
a third drift region disposed in the fourth well and having the second conductivity type; and
a fourth drift region disposed in the sixth well and having the first conductivity type,
wherein the first doped region is disposed in the first drift region, the second doped region is disposed in the second drift region, the third doped region is disposed in the third drift region, and the fourth doped region is disposed in the fourth drift region.

13. An ESD protection device to protect a core circuit coupled between a first power terminal and a second power terminal, comprising:
a substrate having a first conductivity type;
a first well disposed in the substrate and having a second conductivity type;
a second well disposed in the first well and having the first conductivity type;
a first doped region disposed in the first well and having the first conductivity type;
a second doped region disposed in the second well and having the second conductivity type;
a third well disposed in the substrate and having the second conductivity type;
a fourth well disposed in the third well and having the first conductivity type;
a third doped region disposed in the fourth well and having the second conductivity type;
a fourth doped region disposed in the third well and having the first conductivity type; and
a first separation structure disposed in the substrate to separate the first well from the second well,
wherein:
the first and second doped regions are coupled to the first power terminal, and the third and fourth doped regions are coupled to the second power terminal.

14. The ESD protection device as claimed in claim 13, further comprising:
a fifth well disposed in the first well and having the second conductivity type; and
a sixth well disposed in the third well and having the second conductivity type,
wherein the first doped region is disposed in the fifth well, and the fourth doped region is disposed in the sixth well.

15. The ESD protection device as claimed in claim 14, further comprising:
a first isolation structure isolating the first doped region from the second doped region; and
a second isolation structure isolating the third doped region from the fourth doped region.

16. The ESD protection device as claimed in claim 15, further comprising:
a third isolation structure isolating the second doped region from the third doped region.

17. The ESD protection device as claimed in claim 16, further comprising:
a seventh well disposed under the third isolation structure.

18. The ESD protection device as claimed in claim 17, wherein the first separation structure penetrates through the third isolation structure and the seventh well.

19. The ESD protection device as claimed in claim 18, further comprising:
a second separation structure disposed in the substrate to separate the first well from the first separation structure; and
a third separation structure disposed in the substrate to separate the first separation structure from the third well.

20. The ESD protection device as claimed in claim 19, wherein the second separation penetrates through the second isolation structure and the seventh well, and the third separation structure penetrates the second isolation structure and the seventh well.
